(19) United States
(12) Patent Application Publication
(10) Pub. No.: US 2014/0339619 A1
(43) Pub. Date: Nov. 20, 2014

(54) SEMICONDUCTOR DEVICE

(71) Applicant: PS4 LUXCO S.A.R.L., Luxembourg (LU)

(72) Inventor: Kazutaka MANABE, Tokyo (JP)

(73) Assignee: PS4 LUXCO S.A.R.L., Luxembourg (LU)

(21) Appl. No.: 14/277,891

(22) Filed: May 15, 2014

(30) Foreign Application Priority Data
May 15, 2013 (JP) 2013-103351

(51) Int. Cl. H01L 27/108; H01L 29/10

(52) U.S. Cl. CPC H01L 27/10823; H01L 29/105
USPC 257/306

(57) ABSTRACT

Problem: To prevent an excess charge from accumulating in a channel region of a transistor.

Solution: The semiconductor device 1, includes: a semiconductor substrate 10 of a p-type having a principal surface 10a; an element isolation insulating film 13₁ that partitions one end of an active region K₁ embedded in the principal surface 10a; a gate electrode 31₁ embedded interposing a gate insulating film 30 in a gate trench GT₁ provided on the principal surface 10a so as to pass through the active region K₁; a semiconductor pillar P₁ disposed between the gate trench GT₁ and the element isolation insulating film 13₁; an upper diffusion layer 20₁ of an n-type disposed on an upper part of the semiconductor pillar P₁; a lower diffusion layer 21₁ of an n-type disposed to span from a lower side of the gate trench GT₁ to a lower side of the semiconductor pillar P₁; and a side face diffusion layer 11₁ disposed between the element isolation insulating film 13₁ and the semiconductor pillar P₁ and containing an impurity of a p-type having a concentration higher than an impurity concentration of the lower diffusion layer 21₁.

### FIELD OF THE INVENTION

The present invention relates to a semiconductor device, and particularly relates to a semiconductor device having a structure where a gate electrode of a transistor is embedded in a semiconductor substrate.

### BACKGROUND

There have been remarkable trends in miniaturization in transistors in recent years for semiconductors such as dynamic random access memory (DRAM) with significant advances in short channel effects. This is problematic in the case of DRAM because it is directly linked to degradation of retention characteristics and writing characteristics of the memory cell.

Therefore, in recent years, in place of a conventional planar type transistor having a flat channel region, use of transistors having a three dimensional channel region structure are being studied. Specific examples of this type of transistor are known to be a trench type transistor disclosed in Patent Documents 4 and 5, and a fin type transistor disclosed in patent documents 1 to 3. In either of these types, a long channel length, compared to the planar type transistor, can be achieved because the channel can be foamed in not only a plane but also in the height direction which enables suppression of the short channel effect. Furthermore, a structure where the gate electrode is embedded in the semiconductor substrate allows the gate electrode to not protrude from the surface of the semiconductor substrate, and thus achieves an advantage in that layout and processing for various configurations (such as cell capacitors and bit lines in the case of DRAM) are made easier.

### REFERENCE DOCUMENTS

### Patent Documents

Patent Document 1: Japanese Unexamined Patent Application Publication 2005-064500

Patent Document 2: Japanese Unexamined Patent Application Publication 2007-027753

Patent Document 3: Japanese Unexamined Patent Application Publication 2007-305827

Patent Document 4: Japanese Unexamined Patent Application Publication 2012-134439

Patent Document 5: Japanese Unexamined Patent Application Publication 2012-248686

### SUMMARY OF THE INVENTION

### Problem to be Solved by the Invention

Incidentally, the DRAM disclosed in Patent Document 5 is provided on a main surface of the semiconductor substrate with an active region that extends in a first direction, and first and second trenches that respectively extend in a second direction that crosses the first direction and are disposed so as to cross the active region. One end (the end portion nearer to the first trench) of the first direction of the active region is partitioned by a first element isolation region, and the other end (the end portion nearer to the second trench) of the first direction of the active region is partitioned by a second element isolation region.

Two cell transistors (first and second cell transistors) are provided in the active region. A gate electrode is embedded interposing a gate insulating film in respective inner portions of the first and second trenches, and the gate electrode embedded in the first trench configures a gate electrode of the first cell transistor, and the gate electrode embedded in the second trench configures a gate electrode of the second cell transistor.

Partitioned within the active region are an inter-trench region positioned between the first and second trenches, a first semiconductor pillar positioned between the first trench and the first element isolation region, and a second semiconductor pillar positioned between the second trench and the second element isolation region. Of these, the inter-trench region is provided with an impurity diffusion layer (hereinafter referred to as the “bit line diffusion layer”) connected to a bit line. The bit line diffusion layer is common to the first and second cell transistors and also extends from a lower side of the inter-trench region to regions along respective lower surfaces of the first and second trenches. Meanwhile, a top portion of the first semiconductor pillar is provided with an impurity diffusion layer (upper diffusion layer) connected to a first cell capacitor that corresponds to the first cell transistor. By this, a channel region of the first cell transistor is formed on the first semiconductor pillar. Similarly, a top portion of the second semiconductor pillar is provided with an impurity diffusion layer (upper diffusion layer) connected to a second cell capacitor that corresponds to the second cell transistor. By this, a channel region of the second cell transistor is formed on the second semiconductor pillar.

After the first and second trenches are formed, a portion of the bit line diffusion layer that extends to regions along respective lower surfaces of the first and second trenches is fanned by implanting impurity ions into the bottom surface of these. In this manner, forming the bit line diffusion layer also on the bottom surface serves to relax the junction field in the upper diffusion layer and to improve retention characteristics of the memory cell. However meanwhile, as the widths of the first and second semiconductor pillars become narrower in conjunction with advancements in miniaturization, a portion of the impurity ions implanted in the bottom surface of the first and second trenches may, at times, reach the first and second element isolation layers by passing the first and second semiconductor pillars. In this manner, the bit line diffusion layer may form an occlusion in the bottom of the first and second semiconductor pillars, and the channel region formed in the first and second semiconductor pillars may become isolated by the bit line diffusion layer from the region (hereinafter referred to as the “lower region”) in the semiconductor substrate that expands to the lower side of the first and second semiconductor pillars.

It is known that excess electrical charge is generated within the channel region during the On Off operations of the cell transistor. This excess electrical charge, normally, is emitted to the ground or the like through the lower region from the channel region. However, when the channel region and the lower region are isolated as described above, emission of the electrical charge through the lower region no longer functions. As a result, the excess charge accumulates in the channel region which brings about fluctuation in the threshold, thereby causing instability in the operation of the cell transistor. The applicants refer to this as a “floating body effect.”

### SUMMARY OF THE INVENTION

A semiconductor device according to one aspect of the present invention, includes: a semiconductor substrate of a first conductivity type having a principal surface; a first element isolation insulating film that partitions one end of an active region embedded in the semiconductor substrate; a gate electrode embedded interposing a gate insulating film in a trench provided on the semiconductor substrate so as to pass through the active region; a semiconductor pillar disposed between the trench and the element isolation insulating film; an upper diffusion layer of a second conductivity type disposed on an upper part of the semiconductor pillar; a lower diffusion layer of a second conductivity type disposed to span from a lower side of the trench to a lower side of the semiconductor pillar; and a side face diffusion layer disposed between the element isolation insulating film and the semiconductor pillar and containing an impurity of a first conductivity type having a concentration higher than an impurity concentration of the lower diffusion layer.

A semiconductor device according to another aspect of the present invention, includes: a semiconductor substrate of a first conductivity type having a principal surface; a first element isolation insulating film that partitions one end of an active region embedded in the semiconductor substrate; a second element isolation insulating film that partitions an other end of the active region embedded in the semiconductor substrate; a first gate electrode embedded interposing a gate insulating film in a first trench provided on the semiconductor substrate so as to pass through the active region; a second gate electrode embedded interposing a gate insulating film in a second trench provided on the semiconductor substrate so as to pass through a region of the active region between the first trench and the second element isolation insulating film; a first semiconductor pillar disposed between the first trench and the first element isolation insulating film; a second semiconductor pillar disposed between the second trench and the second element isolation insulating film; a first upper diffusion layer of a second conductivity type disposed on an upper part of the first semiconductor pillar; a second upper diffusion layer of a second conductivity type disposed on an upper part of the second semiconductor pillar; an inter-trench diffusion layer of a second conductivity type disposed between the first trench and the second trench; a lower diffusion layer of the second conductivity type disposed to span from a lower side of the first semiconductor pillar to a lower side of the second semiconductor pillar and connected to the inter-trench diffusion layer; a first side face diffusion layer disposed between the first element isolation insulating film and the first semiconductor pillar and containing an impurity of a first conductivity type having a concentration higher than the impurity concentration of the first lower diffusion layer; and a second side face diffusion layer disposed between the second element isolation insulating film and the second semiconductor pillar and containing an impurity of a first conductivity type having a concentration higher than the impurity concentration of the first lower diffusion layer.

A semiconductor device according to still another aspect of the present invention, includes: a semiconductor substrate of a first conductivity type having a principal surface; a first element isolation insulating film that partitions one end of a first active region and one end of a second active region embedded in the semiconductor substrate; a first gate electrode embedded interposing a gate insulating film in a first trench provided on the semiconductor substrate so as to pass through a first active region; a third gate electrode embedded interposing a gate insulating film in a third trench provided on the semiconductor substrate so as to pass through a second active region; a first semiconductor pillar disposed between the first trench and the first element isolation insulating film; a third semiconductor pillar disposed between the third trench and the first element isolation insulating film; a first upper diffusion layer of a second conductivity type disposed on an upper part of the first semiconductor pillar; a third upper diffusion layer of the second conductivity type disposed on an upper part of the third semiconductor pillar; a first lower diffusion layer of the second conductivity type disposed to span from a lower side of the first trench to a lower side of the first semiconductor pillar; a second lower diffusion layer of the second conductivity type disposed to span from a lower side of the third trench to a lower side of the third semiconductor pillar; a first side face diffusion layer disposed between the first element isolation insulating film and the first semiconductor pillar and containing an impurity of a first conductivity type having a concentration higher than the impurity concentration of the first lower diffusion layer; and a third side face diffusion layer disposed between the first element isolation insulating film and the third semiconductor pillar and containing an impurity of the first conductivity type having a concentration higher than the impurity concentration of the second lower diffusion layer.

### EFFECT OF THE INVENTION

With the present invention, an electrical connection can be secured by a side face diffusion layer between a channel region formed in a semiconductor pillar and a region (lower region) in a semiconductor substrate that expands to a lower side of a semiconductor pillar. Accordingly, an excess charge can be prevented from accumulating in the channel region.

### BRIEF DESCRIPTION OF THE DRAWINGS

FIG. 1A is a horizontal cross-sectional view of a semiconductor device 1 according to a preferred first embodiment of the present invention and corresponds to the B-B line illustrated in FIG. 1B, and FIG. 1B is a cross-sectional view of the semiconductor device 1 according to the A-A line illustrated in FIG. 1A.

FIG. 2A is a plan view of the semiconductor device 1 in a manufacturing process, and FIG. 2B is a cross-sectional view of the semiconductor device 1 according to the A-A line illustrated in FIG. 1A.

FIG. 3A is a plan view of the semiconductor device 1 in a manufacturing process, and FIG. 3B is a cross-sectional view of the semiconductor device 1 according to the A-A line illustrated in FIG. 3A.

FIG. 4A is a plan view of the semiconductor device 1 in a manufacturing process, and FIG. 4B is a cross-sectional view of the semiconductor device 1 according to the A-A line illustrated in FIG. 4A.

FIG. 5A is a plan view of the semiconductor device 1 in a manufacturing process, and FIG. 5B is a cross-sectional view of the semiconductor device 1 according to the A-A line illustrated in FIG. 5A.

FIG. 6A is a plan view of the semiconductor device 1 in a manufacturing process, and FIG. 6B is a cross-sectional view of the semiconductor device 1 according to the A-A line illustrated in FIG. 6A.

FIG. 7A is a plan view of the semiconductor device 1 in a manufacturing process, and FIG. 7B is a cross-sectional view of the semiconductor device 1 according to the A-A line illustrated in FIG. 7A.

FIG. 8A is a horizontal cross-sectional view of the semiconductor device 1 according to a preferred second embodiment of the present invention and corresponds to the B-B line illustrated in FIG. 8B, and FIG. 8B is a cross-sectional view of the semiconductor device 1 according to the A-A line illustrated in FIG. 8A.

FIG. 9A is a plan view of the semiconductor device 1 in a manufacturing process, and FIG. 9B is a cross-sectional view of the semiconductor device 1 according to the A-A line illustrated in FIG. 9A.

### DETAILED DESCRIPTION

Preferred embodiments pursuant to the present invention will now be explained in detail below, referencing the appended drawings. Note that, for the drawings used in the following descriptions, characteristic portions may be illustrated enlarged for convenience and ease in understanding the characteristics of the invention. In doing so, the dimensional proportions of the components may not be the same as that in the actual components. Further, in the following description, the materials, dimensions, and the like exemplified therein represent one example, and the present invention is not necessarily limited to these, and such may be appropriately modified and implemented within a scope that does not violate the essence thereof.

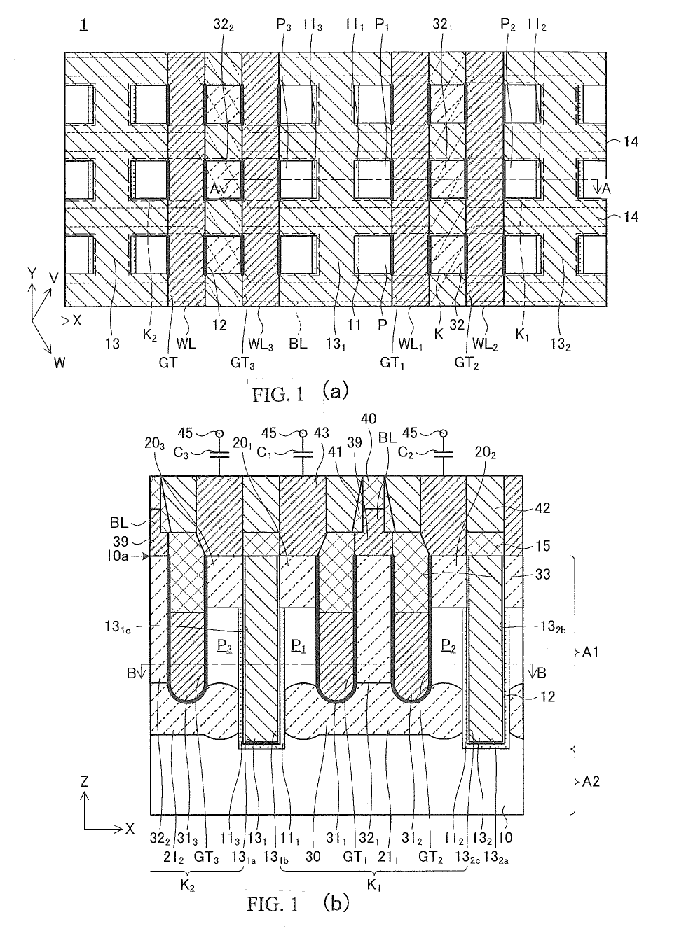

First, with reference to FIG. 1, a structure of the semiconductor device 1 according to the first embodiment of the present invention is described. Note that, in FIG. 1B, an illustration of the configuration positioned above the interlayer insulating film 42 described below is omitted.

The semiconductor device 1 functions as DRAM and has a configuration in which a memory cell region, where a plurality of memory cells are disposed in line in a matrix, and a peripheral circuit region, where a circuit is formed for controlling operation of the memory cells in the memory cell region, are disposed on a principal surface 10a of a semiconductor substrate 10. FIG. 1A illustrates only a portion of the memory cell region thereof. The type of semiconductor substrate 10 is not particularly limited, but use of a p-type (first conductivity type) silicon single crystal substrate as the semiconductor substrate 10 is preferred. The semiconductor substrate 10 in the following description is a p-type silicon single crystal substrate.

As illustrated in FIG. 1A, a plurality of active regions K are disposed in line in a matrix on the principal surface 10a of the semiconductor substrate 10. Each active region K corresponds to two memory cells, respectively, and more specifically, two cell transistors and respective cell capacitors that correspond thereto are disposed in one active region K.

Each active region K is partitioned by a plurality of element isolation insulating films 13 and 14 (element isolation regions) respectively embedded in the principal surface 10a of the semiconductor substrate 10. The element isolation insulating film 13 is configured of an insulating film embedded in a trench that extends in a Y direction (first direction), and the element isolation insulating film 14 is configured of an insulating film embedded in a trench that extends in an X direction (a direction that crosses the first direction, a second direction)). The element isolation insulating films 13 and 14, as illustrated in FIG. 1B, are embedded in corresponding trenches interposing a liner oxide film 12. Note that an illustration of the liner oxide film 12 is omitted in FIG. 1A.

Between the bottom surface of the element isolation insulating films 13 and 14 and the principal surface 10a of the semiconductor substrate 10 is an element forming region Al, as illustrated in FIG. 1B. Meanwhile, a region more to an inner side of the semiconductor substrate 10 than the element forming region A1 is a lower region A2. In the lower region A2, substrate electric potential is supplied from the outside through a terminal not illustrated.

A spacing at which the element isolation insulating film 13 is disposed is set to minimal processing dimensions for lithography, and a spacing at which the element isolation insulating film 14 is disposed is set to five times the minimal processing dimensions for lithography so as to be respectively equivalent. Accordingly, a length in the X direction of the active region K is equivalent to five times the minimal processing dimensions, and a length in the Y direction is equivalent to the minimal processing dimensions. That is, the active region K extends in the X direction. Note that, in FIG. 1A, the active region K is depicted as a rectangle, but other shapes are also possible such as a parallelogram, rounded rectangle, and the like.

Here, in FIGS. 1A and 1B and in the descriptions of the drawings to follow, subscript numbers are attached to the reference numeral, such as with active regions K₁ and K₂. The subscript numbers are attached for convenience of description, and the specific structure is the same without the subscript numbers. As illustrated in the drawing, the active regions K₁ and K₂ (first and second active regions) are adjacently disposed in the X direction (second direction). One end in the X direction of the active region K₁ and one end in the X direction of the active region K₂, respectively, are partitioned by an element isolation insulating film 13₁ (first element isolation insulating film). An other end in the X direction of the active region K₁ is partitioned by an element isolation insulating film 13₂ (second element isolation insulating film)

A plurality of gate trenches GT are further provided on the principal surface 10a of the semiconductor substrate 10 extending respectively in the Y direction. This plurality of gate trenches GT is disposed so that two gate trenches GT pass through one active region K. As illustrated in FIG. 1A, there are two gate trenches GT that pass through the active region K₁, a gate trench GT₁ and a gate trench GT₂ (first and second trenches). The gate trench GT₂ is disposed so as to pass through a region between the gate trench GT₁ and the element isolation insulating film 13₂. Further, of the two gate trenches GT that pass through the active region K₂, the one that passes through a position near the active region K₁ is a gate trench GT₃ (third trench).

A gate electrode 31 configuring a control terminal for a corresponding cell transistor is embedded in the gate trench GT interposing a gate insulating film 30. For example, a gate electrode 31₁ (first gate electrode) is embedded in the gate trench GT₁, and a gate electrode 31₂ (second gate electrode) is embedded in the gate trench GT₂, and a gate electrode 31₃ (third gate electrode) is embedded in the gate trench GT₃, respectively. The gate electrodes 31 are embedded in the lower portion of the gate trenches GT, and a cap insulating film 33 that covers the top surface of the gate electrode 31 is embedded in the top portion of the gate trench GT. The top surface of the cap insulating film 33 configures the same plane as the top surface of an interlayer insulating film 15 that covers the principal surface 10a of the semiconductor substrate 10. Each gate electrode 31 in the gate trenches GT configures a word line of DRAM, respectively.

The active region K is divided into three regions by two of the gate trenches GT. Of these, an inter-trench diffusion layer 32 that includes n-type (second conductivity type) impurity ions is disposed in regions between the gate trenches GT (inter-trench region). The other two regions make up channel regions for corresponding cell transistors and respectively configure semiconductor pillars P.

In describing the active region K₁in further detail, an entrenched diffusion layer 32₁ (first connecting diffusion layer) is disposed between the gate trench GT₁ and the gate trench GT₂, a semiconductor pillar P₁ (first semiconductor pillar) is disposed between the gate trench GT₁ and the element isolation insulating film 13₁, and a semiconductor pillar P₂ (second semiconductor pillar) is disposed between the gate trench GT₂ and the element isolation insulating film 13₂. Further, with regard to the active region K₂, a semiconductor pillar P₃ (third semiconductor pillar) is disposed between the gate trench GT₃ and the element isolation insulating film 13₁, and the inter-trench diffusion layer 32₂ (second connecting diffusion layer) is disposed between the gate trench GT₃and another gate trench GT.

The top surface of the inter-trench diffusion layer 32 contacts the bottom surface of a bit line BL interposing a bit line contact plug 39 that passes through the interlayer insulating film 15 described above. The bit line BL is a snake line shaped conductor that extends in an overall X direction while bending in an illustrated V direction (a direction inclined at a predetermined angle relative to the X direction) and in a W direction (a direction inclined at a predetermined angle in an opposite direction to the V direction relative to the X direction) so as to avoid cell capacitors C described below. As illustrated in FIG. 1B, the top surface of the bit line BL is covered by a cover insulating film 40, and a liner film 41 is provided on the side surface of the bit line BL and the cover insulating film 40. An interlayer insulating film 42 is formed on the top surface of the interlayer insulating film 15, and the top surface of the cover insulating film 40 configures the same plane as the top surface of the interlayer insulating film 42. As is evident from FIG. 1A, each bit line BL is connected in common to the inter-trench diffusion layer 32 of the respective plurality of active regions K aligned in the X direction.

An upper diffusion layer 20 that includes n-type impurity ions is disposed on the top part of each semiconductor pillar P. For example, an upper diffusion layer 20₁ (first upper diffusion layer) is embedded in the top portion of the semiconductor pillar P₁, an upper diffusion layer 20₂ (second upper diffusion layer) is embedded in the top portion of the semiconductor pillar P₂, and an upper diffusion layer 20₃ (third upper diffusion layer) is embedded in the top portion of the semiconductor pillar P₃, respectively.

The upper diffusion layer 20, as illustrated in FIG. 1B, is connected to one side electrode (lower electrode) of corresponding cell capacitors C interposing a capacity contact plug 43 that passes through the interlayer insulating films 15 and 42. For example, the upper diffusion layers 20₁ to 20₃, respectively, are each connected to one side electrode of the cell capacitors C₁ to C₃ (first through third cell capacitors). The other side electrode (upper electrode) of the cell capacitors C is connected to a common plate electrode 45. Ground potential is supplied to the plate electrode 45 from the outside.

Lower diffusion layers 21 that include n-type impurity ions are disposed in the lower portion of the element forming region A1 for each active region K. Described in further detail below, the lower diffusion layers 21 are formed by implanting n-type impurity ions in the bottom surface of each gate trench GT.

As an example of the active region K₁, the lower diffusion layer 21₁ (first lower diffusion layer) is disposed to span from the lower side of the semiconductor pillar P₁ to the lower side of the semiconductor pillar P₁. The lower diffusion layer 21₁ disposed in this manner, naturally, is also formed on the lower side of the gate trenches GT₁ and GT₂, and the inter-trench diffusion layer 32₁. The portion formed on the lower side of the inter-trench diffusion layer 32₁ of the lower diffusion layer 21₁ is connected to the inter-trench diffusion layer 32₁ at the top surface. A lower diffusion layer 21₂ (second lower diffusion layer) connected to the inter-trench diffusion layer 32₂ is also similarly disposed on the active region K₂.

With the configuration described above, two cell transistors connected between respective cell capacitors C and bit lines BL are configured in respective active regions K. In the example of the active region K₁ described above, the first cell transistor is a MOSFET (metal-oxide-semiconductor field-effect transistor) that has the upper diffusion layer 20₁ on one side of the source/drain with the lower diffusion layer 21₁ and the inter-trench diffusion layer 32₁ on the other side of the source/drain, and where the gate electrode 31₁ is used as the gate electrode. The channel region of the cell transistor is formed in a semiconductor pillar P₁. The second cell transistor is a MOSFET that has the upper diffusion layer 20₂ on one side of the source/drain with the lower diffusion layer 20₁ and the inter-trench diffusion layer 32₁ on the other side of the source/drain, and where the gate electrode 31₂ is used as the gate electrode. The channel region of the cell transistor is formed in a semiconductor pillar P₂. An operation of the cell transistor is further described in detail below.

Between the element isolation insulating film 13 and the semiconductor pillar P, a side face diffusion layer 11 is disposed containing p-type impurities having a concentration higher than an impurity concentration of the lower diffusion layer 21. The side face diffusion layer 11, in addition to being formed on a side face opposing the semiconductor pillar P of the element isolation insulating film 13, is also formed on a bottom surface of the element isolation insulating film 13.

In describing the active layers K₁ and K₂ in further detail, first, the element isolation insulating film 13₁ is configured having a bottom surface 13₁ₐ, a side face 13_{1b} that opposes the semiconductor pillar P₁, and a side face 13_{1c} that opposes the semiconductor pillar P₃. Of these, the side face diffusion layer 11₁ (first side face diffusion layer) is formed on the side face 13_{1b}, and a side face diffusion layer 11₃ (third side face diffusion layer) is formed on the side face 13₁. These side face diffusion layers 11₁ and 11₃ configure an integrated single side face diffusion layer 11 together with the side face diffusion layer 11 formed on the bottom surface 13₁ₐ. Further, the element isolation insulating film 13₂ is configured having a bottom surface 13₂ₐ, a side face 13₂, opposing the semiconductor pillar P₂, and a side face 13_{2b} positioned on the opposite side of the side face 13_{2b}. Of these, the side face 13_{2c} has the side face diffusion layer 11₂ (second side face diffusion layer) formed thereon. The side face diffusion layer 11₂ configures an integrated single side face diffusion layer 11 together with the side face diffusion layer 11 formed on the bottom surface 13₂ₐ and the side face 13_{2b}.

The specific impurity concentration of the side face diffusion layer 11 is appropriately determined according to the impurity concentration of the semiconductor substrate 10 and the impurity concentration of the lower diffusion layer 21. A specific example is when the concentration of the p-type impurities contained in the semiconductor substrate 10 is 5×10¹⁵ atoms/cm³, and the concentration of n-type impurities contained in the lower diffusion layer 21 is 1×10¹⁹ atoms/cm³, the concentration of the p-type impurities contained in the side face diffusion layer 11 must be a concentration higher than 1×10¹⁹ atoms/cm³. Meanwhile, while there is no particular upper limit to the concentration of the p-type impurities contained in the side face diffusion layer 11, if it is made an excessively high concentration, the junction field becomes high with the risk of increasing junction leakage current, and therefore it is preferred that the concentration is held to 5×10¹⁹ atoms/cm³ or below. In summary, it is preferred that the concentration of the p-type impurities contained in the side face diffusion layer 11 is higher than the concentration of the n-type impurities contained in the lower diffusion layer 21 and does not exceed a concentration of more than 0.5 digits more than the concentration of the n-type impurities contained in the lower diffusion layer 21. The reason the impurity concentration of the side face diffusion layer 11 is set in this manner is to maintain the side face diffusion layer 11 as a p-type even if, for example, n-type impurities penetrate into the side face diffusion layer 11 when implanting n-type impurity ions to form the lower diffusion layer 21 after formation of the side face diffusion layer 11. Accordingly, a p-type state is maintained in the side face diffusion layer 11 even after the formation of the lower diffusion layer 21.

Further, the thickness (width in the X direction) of a portion formed on the side face of the element isolation insulating film 13 of the side face diffusion layers 11 is preferably ½ or less the width in the X direction of the semiconductor pillar P, ⅕or less is more preferred, and 1/10 or less is most preferred.

An example of a cell transistor in which the semiconductor pillar P₁ in the active region K₁ is the channel region is given below, and effects achieved by providing the side face diffusion layer 11 will be described in detail.

A predetermined positive voltage is applied to the gate electrode 31₁ to form a channel in the inner portion of the semiconductor pillar P₁. By this, the upper diffusion layer 20₁ and the lower diffusion layer 21₁ become conductive and the cell transistor is turned ON. Meanwhile, stopping the above positive voltage to the gate electrode 31₁ cancels the channel in the semiconductor pillar P₁ to make the upper diffusion layer 20₁ and the lower diffusion layer 21₁ to be nonconductive and the cell transistor is turned OFF.

With the ON-OFF operation of this type of cell transistor, excess charge (electron holes) are generated in the channel region of the semiconductor pillar P₁. The side face diffusion layer 11₁ functions as an escape path for this excess charge. In other words, the excess charge generated in the channel region leaks to the lower region A2 through the side face diffusion layer 11₁ and is released to the outside through the power wiring used to supply substrate electric potential connected to the lower region A2. Accordingly, an excess charge can be prevented from accumulating in the channel region.

As described above, with the semiconductor device 1 according to the embodiment, an electrical connection can be secured by the side face diffusion layer 11 between the channel region formed in the semiconductor pillar P and the region (lower region) in the semiconductor substrate that expands to a lower side of the semiconductor pillar P. Accordingly, because the excess charge can be prevented from accumulating in the channel region, cell transistor operation can be stabilized.

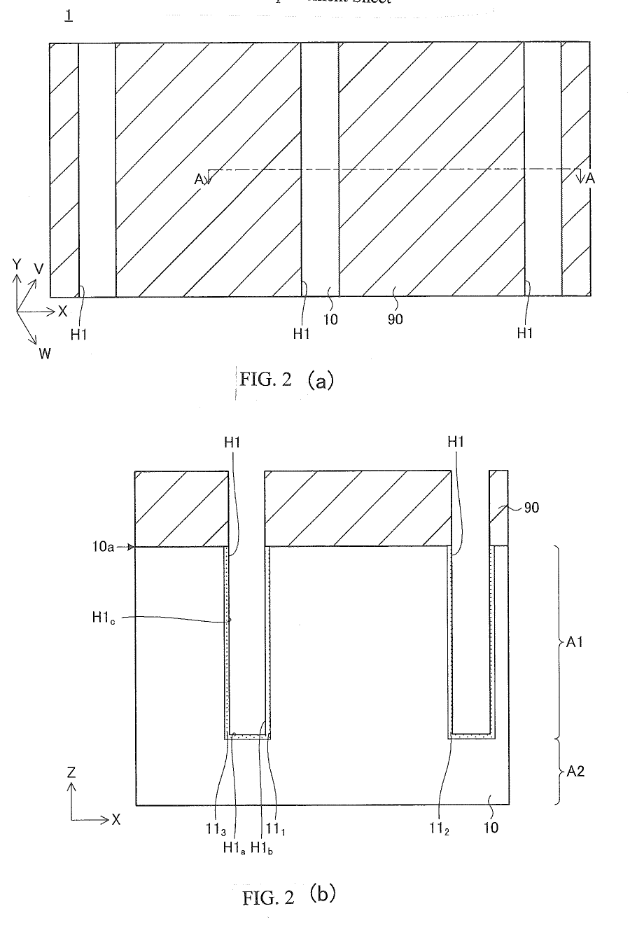

Next, a method for manufacturing a semiconductor device 1 according to this embodiment will be described with reference to FIG. 2 to FIG. 6.

First, to begin with, as illustrated in FIGS. 2A and 2B, a resist 90 is coated on the principal surface 10a of the semiconductor substrate 10, and using photolithography and dry etching, a plurality of element isolation trenches H1 that respectively extend in the Y direction is formed. Note that the element isolation trench H1 may be formed using a so-called double patterning method. After the element isolation trench H1 is formed, impurities of the same characteristic (=p-type) as the impurities in the semiconductor substrate 10 are ion implemented into both side faces H1_{b} and H1_{c} in the X direction of element isolation trench H1 using a so-called oblique injection. The concentration of impurities, as described above, is higher than the concentration of the n-type impurities contained in the lower diffusion layer 21 formed thereafter and does not exceed a concentration of more than 0.5 digits more than the concentration of the n-type impurities contained in the lower diffusion layer 21. In this manner, the ion implanted impurities are integrated with each element isolation trench H1 to configure the side face diffusion layer 11. The side face diffusion layer 11 is formed not only on the side faces H1_{b} and H1_{c} but is also formed on the bottom surface H1 ₐ of the element isolation trench H1, but this is not intentional. However, this is not particularly problematic even if the side face diffusion layer 11 is formed on the bottom surface H1ₐ because it has the same characteristics as the side face diffusion layer 11 and the semiconductor substrate 10.

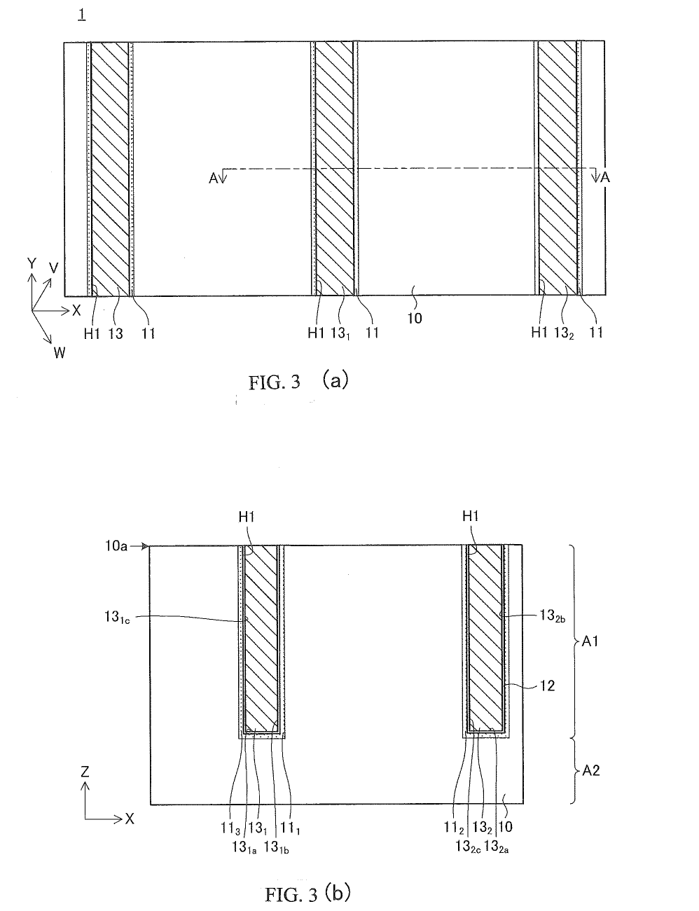

Next, as illustrated in FIGS. 3A and 3B, a liner oxide film 12 (silicon oxide film) is formed on the inner surface of each element isolation trench H1 using thermal oxidation. Note that an illustration of a liner oxide film 12 is omitted in FIG. 3A. Thereafter, a plurality of element isolation insulating films 13 that respectively extend in the Y direction is formed by embedding the silicon oxide film into each element isolation trench H1. Flowable-CVD silicon oxide film produced by AMD is appropriate for use as the silicon oxide film embedded at this time.

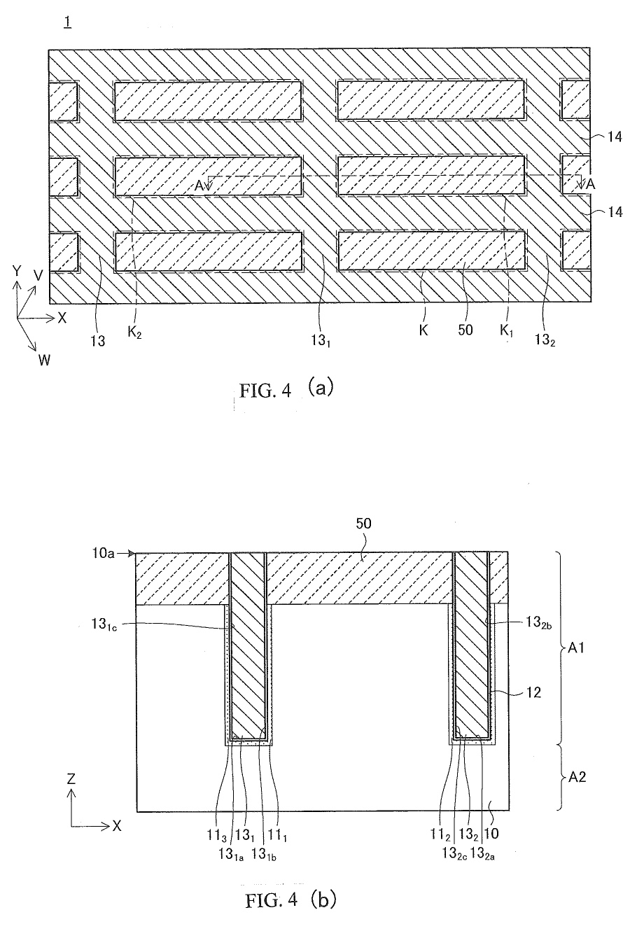

Next, as illustrated in FIGS. 4A and 4B, using photolithography and dry etching, the plurality of element isolation trenches that extend respectively in the X direction is formed on the surface of the semiconductor substrate 10, and the formation of the thermal oxide film and the embedding of the silicon oxide film are performed in the same manner at the same time as the formation of the element isolation insulating film 13 to form the plurality of element isolation insulating films 14 that extend respectively in the X direction. By this, the plurality of active regions K disposed in a matrix shape are partitioned. Subsequently, impurities having opposite characteristics (=n-type) to the impurities in the semiconductor substrate 10 are ion implanted at low energy into the top surface of each active region K. By this, an impurity diffusion layer 50, that later becomes the upper diffusion layer 20, is formed on the top part of each active region K.

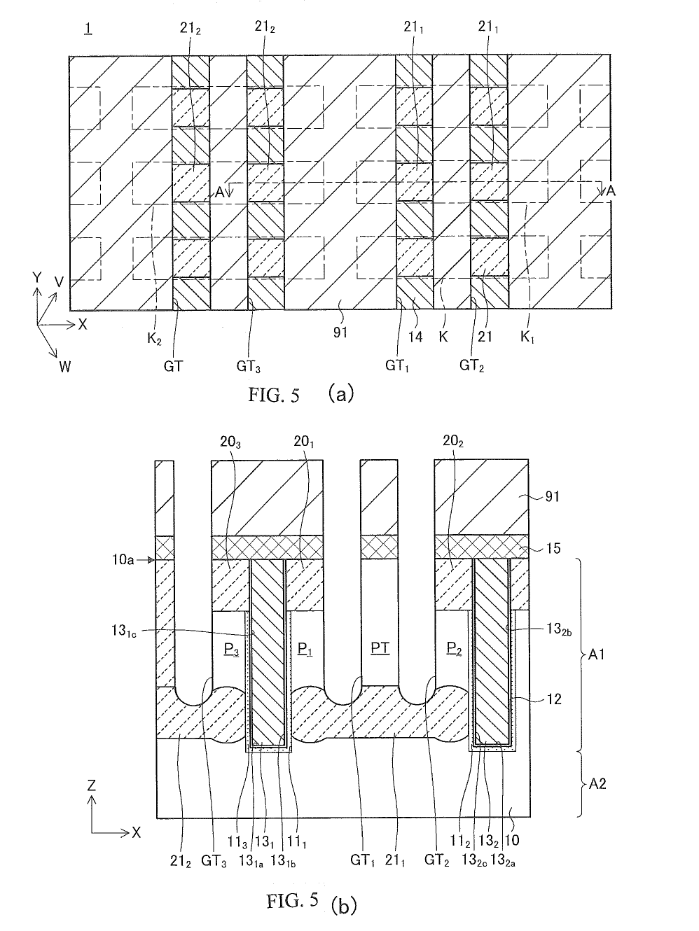

Next, as illustrated in FIGS. 5A and 5B, the interlayer insulating film 15, which is the silicon oxide film, is formed over the entire surface at a thickness of, for example, 20 nm, and a resist 91 is further coated. Further, using photolithography and dry etching, a plurality of gate trenches GT is formed that respectively extends in the Y direction. Note that a so-called double patterning method may also be used for the formation of the gate trench GT. By this, the plurality of semiconductor pillars P that include the semiconductor pillars P₁, P₂, and P₃ illustrated in FIG. 5B are formed between the gate trenches GT and the element isolation insulating films 13. Further, semiconductor pillar PT is formed between adjacent gate trenches GT.

After the gate trenches GT are formed, impurities of opposite characteristics n-type) to the impurities in the semiconductor substrate 10 are ion implanted into the bottom surface of the gate trenches GT. By this, the lower diffusion layers 21 are formed. Note that forming the lower diffusion layers 21 on the bottom surfaces of the gate trenches GT in this manner serves to relax the junction field in the upper diffusion layer 20 (storage node side diffusion layer) and to improve retention characteristics of the memory cell. Furthermore, ion implantation into the bottom surfaces of the gate trenches GT is appropriately performed using a local channel implant (LCI) method, specifically.

The impurity ions implanted into the bottom surfaces of the gate trenches GT, as illustrated in FIG. 5B, significantly overhang also into the lower side of the semiconductor pillar P and reach the side face diffusion layer 11. However, as described above, because the impurity concentration of the side face diffusion layer 11 is higher than the impurity concentration of the lower diffusion layer 21, the p-type state is maintained in the side face diffusion layer 11. Accordingly, even after forming the lower diffusion layer 21, the semiconductor pillar P and the lower region A2 are electrically connected through the side face diffusion layer 11.

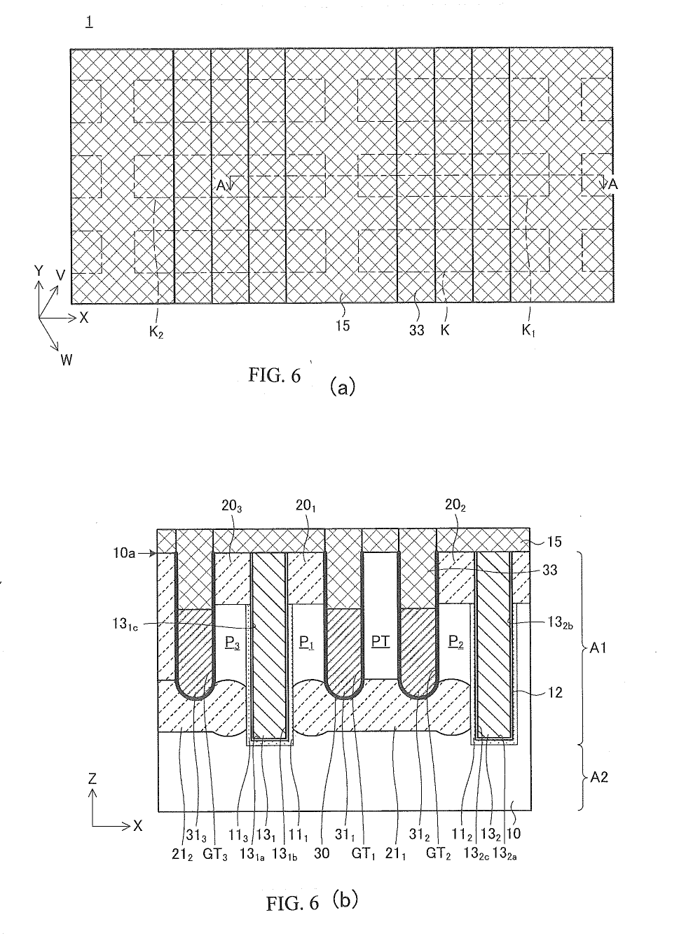

Next, as illustrated in FIGS. 6A and 6B, after forming a gate insulating film 30 on the inner surface of the gate trenches GT using thermal oxidation and after a tungsten film is further formed at a thickness such that a gate trench GT is embedded, the gate electrode 31 is formed in the gate trench GT by etching back the tungsten film. Note that, the etch back of the tungsten film may be performed until the top surface of the gate electrode 31 is in a position just below the bottom surface of the upper diffusion layer 20. After this, the silicon nitride film is formed and back-etching is performed for embedding by the cap insulating film 33 into the gate trench GT. The cap insulating film 33 formed in this manner is integrated with the interlayer insulating film 15.

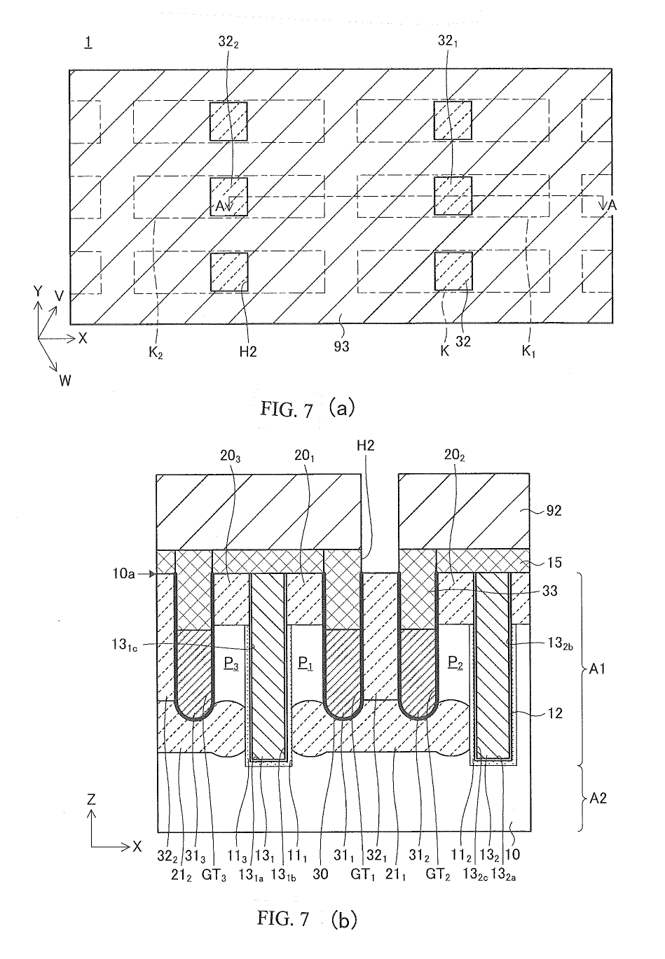

Next, as illustrated in FIGS. 7A and FIG. 7B, a resist 92 is coated over the entire surface, and using photolithography and dry etching, a bit line contact trench H2 is formed on the interlayer insulating film 15 to expose the semiconductor pillar PT (a region between adjacent gate trenches GT). Further, impurities having opposite characteristics (=n-type) as the impurities in the semiconductor layer 10 are ion implanted into the semiconductor pillar PT through the bit line contact trench H2. By this, the inter-trench diffusion layer 32 is formed in the region between the adjacent gate trenches GT. The ion implantation at this time is implemented so that the inter-trench diffusion layer 32 is integrated with the lower diffusion layer 21 therebelow. After that, as illustrated in FIGS. 1A and 1B, forming the bit line BL, the capacity contact plug 43, the cell capacitor C, and the like completes a semiconductor device 1 according to this embodiment.

As described above, with the manufacturing method of the semiconductor device 1 according to this embodiment, the side phase diffusion layer 11 can be formed between the element isolation insulating film 13 and the semiconductor pillar P. Accordingly, a semiconductor device 1 that provides a cell transistor with stable operation can be obtained.

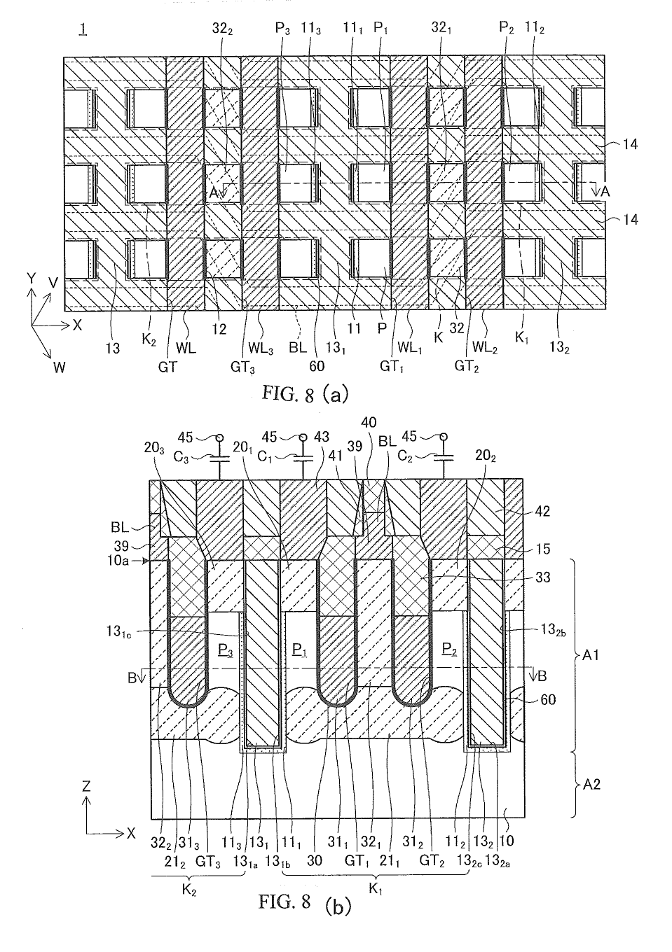

Next, with reference to FIG. 8, a structure of the semiconductor device 1 according to the second embodiment of the present invention is described. Note that, in FIG. 8B, an illustration of the configuration positioned above the interlayer insulating film 42 is omitted.

The semiconductor device 1 according to this embodiment differs from the semiconductor device 1 according to the first embodiment with respect to providing a boron silicon glass (BSG) film 60 between the element isolation insulating film 13 and the semiconductor substrate 10 and is identical to the semiconductor device 1 according to the first embodiment with respect to such other aspects. Note that, although the liner oxide film 12 is not depicted in FIG. 8, the liner oxide film 12, in actuality, is also formed in a similar manner to that described in the first embodiment. The following is a description focusing on the disparate points.

As illustrated in FIGS. 8A and 8B, with the semiconductor device 1 according to this embodiment, the BSG film 60 is provided between the element isolation insulating film 13 and the semiconductor substrate 10. This BSG film 60 (impurity supply film) is to supply boron as a p-type impurity configuring the side face diffusion layer 11 in the semiconductor substrate 10. Accordingly, with the present embodiment, the impurity contained in the side face diffusion layer 11 is boron. A method for manufacturing the semiconductor device 1 according to this embodiment will be described hereinafter in detail.

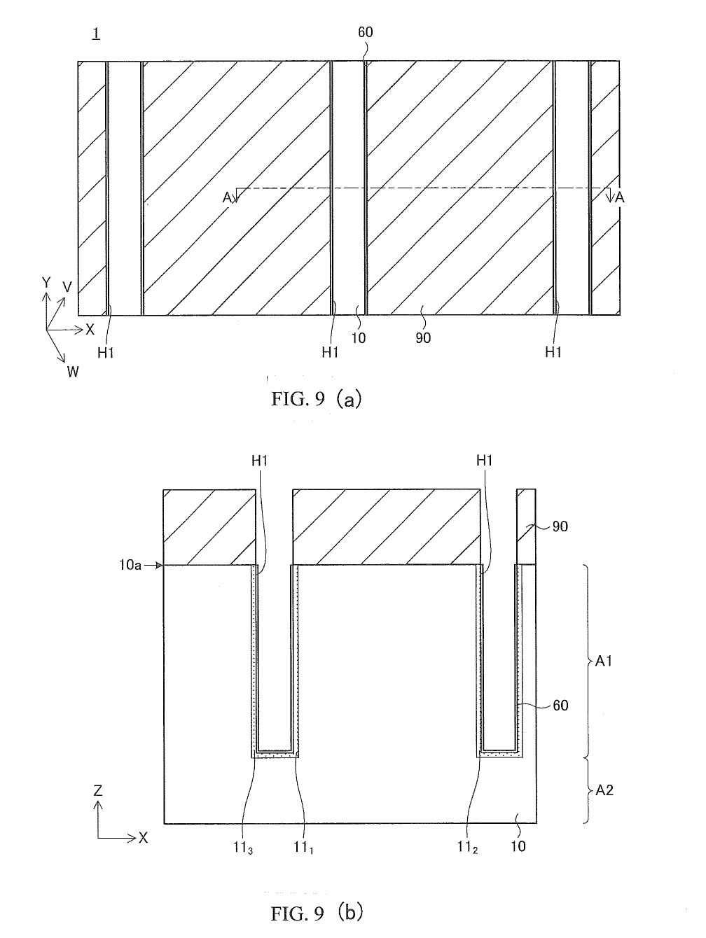

In the method for manufacturing a semiconductor device 1 according to this embodiment, first, as illustrated in FIGS. 9A and 9B, a resist 90 is coated on the principal surface 10a of the semiconductor substrate 10, and using photolithography and dry etching, a plurality of element isolation trenches H1 respectively extending in the Y direction is formed. The element isolation trench H1 itself is the same as that which was formed in the first embodiment. In this embodiment, subsequently, a thin BSG film 60 of approximately 5 nm is formed on the inner surface of this element isolation trench H1. Furthermore, the boron is diffused within the BSG film 60 in a semiconductor substrate 10 by applying a heat treatment. By this, as illustrated in FIG. 9B, the side face diffusion layer 11 is formed. The scope for diffusing boron at this time is half the distance or less to the gate trench GT to be formed thereafter. Although with this method as well, the side face diffusion layer 11 is formed on the bottom surface of the element isolation trench H1, as described in the first embodiment, this is not particularly problematic. Afterwards, implementing a similar process to that as described in the first embodiment completes the semiconductor device 1 according to this embodiment.

As described above, with the manufacturing method of the semiconductor device 1 according to this embodiment as well, the side phase diffusion layer 11 can be framed between the element isolation insulating film 13 and the semiconductor pillar P. Accordingly, a semiconductor device 1 that provides a cell transistor with stable operation can be obtained.

Although preferred embodiments of the present invention were described above, the present invention is not limited to the embodiments above, and various variations are possible within a scope that does not depart from the essence of the present invention, and it goes without saying that such are also included within the scope of the present invention.

For example, in the embodiments described above, the side face diffusion layer 11 was formed over the entire surface of both side faces in the X direction and the bottom surface of the element isolation insulating film 13, however, because the side face diffusion layer 11 functions as an escape path for excess charge generated in the channel region as described above, as long as this is provided between the lower diffusion layer 21 and the element isolation insulating film 13 and can prevent direct contact, it is sufficient. Accordingly, the side face diffusion layer 11 may not necessarily be formed over the entirety of both side faces in the X direction and the bottom surface of the element isolation insulating film 13, and is sufficient if formed in a portion that can demonstrate at least functionality as an escape path for the excess charge generated in the channel region (between the lower diffusion layer 21 and element isolation insulating film 13).

### REFERENCE NUMERALS

A1 Element forming region

A2 Lower region

BL Bit line

C, C₁ to C₃ Cell capacitor

GT, GT₁ to GT₃ Gate trench

H1 Element isolation trench

H2 Bit line contact trench

K, K₁, K₂ Active region

P, P₁ to P₃, PT Semiconductor pillar

1 Semiconductor device

10 Semiconductor substrate

11, 11₁ to 11₃ Side face diffusion layer

12 Liner oxide film

13, 13₁, 13₂, 14 Element isolation insulating film

15, 42 Interlayer insulating film

20, 20₁ to 20₃ Upper diffusion layer

21, 21₁, 21₂ Lower diffusion layer

30 Gate insulating film

31, 31₁ to 31₃ Gate electrode

32, 32₁, 32₂ Inter-trench diffusion layer

33 Cap insulating film

39 Bit line contact plug

40 Cover insulating film

41 Liner film

43 Capacity contact plug

45 Plate electrode

50 Impurity diffusion layer

60 BSG film

90, 91 Resist

1. A semiconductor device, comprising:
a semiconductor substrate of a first conductivity type;
an element isolation insulating film that partitions one end of an active region embedded in the semiconductor substrate;
a gate electrode embedded interposing a gate insulating film in a trench provided on the semiconductor substrate so as to pass through the active region;
a semiconductor pillar disposed between the trench and the element isolation insulating film;
an upper diffusion layer of a second conductivity type disposed on an upper part of the semiconductor pillar;
a lower diffusion layer of a second conductivity type disposed to span from a lower side of the trench to a lower side of the semiconductor pillar; and
a side face diffusion layer disposed between the element isolation insulating film and the semiconductor pillar and containing an impurity of a first conductivity type having a concentration higher than an impurity concentration of the lower diffusion layer.

2. The semiconductor device according to claim 1, wherein:
the element isolation insulating film and the trench extend in a first direction, respectively;
the active region extends in a second direction crossing the first direction; and
the side face diffusion layer is provided on a side face facing the semiconductor pillar of the element isolation insulating film.

3. The semiconductor device according to claim 2, wherein the side face diffusion layer is formed on both side faces and a bottom surface in the second direction of the element isolation insulating film.

4. The semiconductor device according to claim 1, further comprising:
a cell capacitor connected to the upper diffusion layer;
a cell capacitor connected to the upper diffusion layer;
connecting diffusion layers disposed on opposite sides of the semiconductor pillar sandwiching the trench and connected to the lower diffusion layer; and
bit lines connected to the connecting diffusion layers;
wherein the gate electrode is a word line.

5. The semiconductor device according to claim 1, further comprising an impurity supply film disposed between the element isolation insulating film and the side face diffusion layer.

6. A semiconductor device, comprising:
a semiconductor substrate of a first conductivity type;
a first element isolation insulating film that partitions one end of an active region embedded in the semiconductor substrate;
a second element isolation insulating film that partitions an other end of the active region embedded in the semiconductor substrate;
a first gate electrode embedded interposing a gate insulating film in a first trench provided on the semiconductor substrate so as to pass through the active region;
a second gate electrode embedded interposing a gate insulating film in a second trench provided on the semiconductor substrate so as to pass through a region of the active region between the first trench and the second element isolation insulating film;
a first semiconductor pillar disposed between the first trench and the first element isolation insulating film;
a second semiconductor pillar disposed between the second trench and the second element isolation insulating film;
a first upper diffusion layer of a second conductivity type disposed on an upper part of the first semiconductor pillar;
a second upper diffusion layer of a second conductivity type disposed on an upper part of the second semiconductor pillar;
an inter-trench diffusion layer of a second conductivity type disposed between the first trench and the second trench;
a lower diffusion layer of the second conductivity type disposed to span from a lower side of the first semiconductor pillar to a lower side of the second semiconductor pillar and connected to the inter-trench diffusion layer;
a first side face diffusion layer disposed between the first element isolation insulating film and the first semiconductor pillar and containing an impurity of a first conductivity type having a concentration higher than the impurity concentration of the first lower diffusion layer; and
a second side face diffusion layer disposed between the second element isolation insulating film and the second semiconductor pillar and containing an impurity of a first conductivity type having a concentration higher than the impurity concentration of the first lower diffusion layer.

7. A semiconductor device according to claim 6, wherein:
the first and second element isolation insulating films and the first and second trenches extend respectively in a first direction;
the active region extends in a second direction crossing the first direction;
the first side face diffusion layer is provided on a side face facing the first semiconductor pillar of the first element isolation insulating film; and
the second side face diffusion layer is provided on a side face facing the second semiconductor pillar of the second element isolation insulating film.

8. The semiconductor device according to claim 7, wherein:
the first side face diffusion layer is formed on both side faces and a bottom surface in the second direction of the first element isolation insulating film; and
the second side face diffusion layer is formed on both side faces and a bottom surface in the second direction of the second element isolation insulating film.

9. The semiconductor device according to claim 6, further comprising:
a first cell capacitor connected to the first upper diffusion layer;
a second cell capacitor connected to the second upper diffusion layer; and
bit lines connected to the connecting diffusion layers;
wherein the first and second gate electrodes are respectively word lines.

10. A semiconductor device, comprising:
a semiconductor substrate of a first conductivity type;
a first element isolation insulating film that partitions one end of a first active region and one end of a second active region embedded in the semiconductor substrate;
a first gate electrode embedded interposing a gate insulating film in a first trench provided on the semiconductor substrate so as to pass through a first active region;
a third gate electrode embedded interposing a gate insulating film in a third trench provided on the semiconductor substrate so as to pass through a second active region;
a first semiconductor pillar disposed between the first trench and the first element isolation insulating film;
a third semiconductor pillar disposed between the third trench and the first element isolation insulating film;
a first upper diffusion layer of a second conductivity type disposed on an upper part of the first semiconductor pillar;
a third upper diffusion layer of the second conductivity type disposed on an upper part of the third semiconductor pillar;
a first lower diffusion layer of the second conductivity type disposed to span from a lower side of the first trench to a lower side of the first semiconductor pillar;
a second lower diffusion layer of the second conductivity type disposed to span from a lower side of the third trench to a lower side of the third semiconductor pillar;
a first side face diffusion layer disposed between the first element isolation insulating film and the first semiconductor pillar and containing an impurity of a first conductivity type having a concentration higher than the impurity concentration of the first lower diffusion layer; and
a third side face diffusion layer disposed between the first element isolation insulating film and the third semiconductor pillar and containing an impurity of the first conductivity type having a concentration higher than the impurity concentration of the second lower diffusion layer.

11. A semiconductor device according to claim 10, wherein:
the first element isolation insulating film and the first trench extend respectively in a first direction;
the first and second active layers respectively extend in a second direction and cross the first direction;
the first side face diffusion layer is provided on a side face facing the first semiconductor pillar of the first element isolation insulating film; and
the third side face diffusion layer is provided on a side face facing the third semiconductor pillar of the first element isolation insulating film.

12. The semiconductor device according to claim 11, wherein the second side face diffusion layer is formed on both side faces and a bottom surface in the second direction of the first element isolation insulating film.

13. The semiconductor device according to claim 10, further comprising:
a first cell capacitor connected to the first upper diffusion layer;
a third cell capacitor connected to the third upper diffusion layer;
first connecting diffusion layers disposed on opposite sides of the first semiconductor pillar sandwiching the first trench and connected to the first lower diffusion layer; and
second connecting diffusion layers disposed on opposite sides of the third semiconductor pillar sandwiching the third trench and connected to the second lower diffusion layer; and
bit lines connected respectively to the first and second connecting diffusion layers;
wherein the first and third gate electrodes are respectively word lines.

14. The semiconductor device according to claim 1 further comprising:
a second element isolation insulating film that partitions an other end of the first active region embedded in the semiconductor substrate;
a second gate electrode embedded interposing a gate insulating film in a second trench provided on the semiconductor substrate so as to pass through a region of the first active region between the first trench and the second element isolation insulating film;
a second semiconductor pillar disposed between the second trench and the second element isolation insulating film;
a second upper diffusion layer of a second conductivity type disposed on an upper part of the second semiconductor pillar;
an inter-trench diffusion layer of a second conductivity type disposed between the first trench and the second trench; and
a second side face diffusion layer disposed between the second element isolation insulating film and the second semiconductor pillar and containing an impurity of the first conductivity type having a concentration higher than the impurity concentration of the first lower diffusion layer;
wherein the first lower diffusion layer is disposed to span from a lower side of the first semiconductor pillar to a lower side of the second semiconductor pillar.
